(19) United States
(12) Patent Application Publication
(10) Pub. No.: US 2024/0038721 A1
(43) Pub. Date: Feb. 1, 2024

(54) SEMICONDUCTOR DEVICES AND METHODS OF MANUFACTURING THEREOF

(71) Applicant: Taiwan Semicondutor Manufacturing Company, Ltd., Hsinchu (TW)

(72) Inventor: Ming-Fa Chen, Taichung (TW)

(73) Assignee: Taiwan Semicondutor Manufacturing Company, Ltd., Hsinchu (TW)

(21) Appl. No.: 17/874,708

(22) Filed: Jul. 27, 2022

(51) Int. Cl. H01L 25/065; H01L 23/538; H01L 23/48; H01L 23/00; H01L 25/00

(52) U.S. Cl. CPC H01L 25/0652; H01L 23/5386; H01L 23/5381; H01L 23/481; H01L 24/08; H01L 25/50; H01L 2225/06517; H01L 2224/08145

(57) ABSTRACT

A semiconductor device includes a plurality of top semiconductor dies. Each of the plurality of top semiconductor dies can be bonded to a bottom semiconductor die. The semiconductor device includes a redistribution structure disposed opposite the plurality of top semiconductor dies from the plurality of bottom semiconductor dies and comprising a plurality of interconnect structures. A top semiconductor die can connect to another top semiconductor die via a first subset of the plurality of interconnect structures.

### BACKGROUND

Semiconductor devices are ubiquitous in several applications and devices throughout most industries. For example, consumer electronics devices such as personal computers, cellular telephones, and wearable devices may contain several semiconductor devices. Similarly, industrial products such as test instruments, vehicles, and automation systems frequently comprise a large number of semiconductor devices. As semiconductor manufacturing improves, semiconductors continue to be used in new applications which, in turn, leads to increased demands of semiconductor performance, cost, reliability, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts a cross section view of a tile of a semiconductor device, in accordance with some embodiments.

FIG. 2 depicts a cross section view of another tile of a semiconductor device, according to some embodiments.

FIG. 3 depicts an X-Y plane view of a semiconductor device, according to some embodiments.

FIG. 4 depicts an X-Y plane view of another semiconductor device, according to some embodiments.

FIG. 5 depicts a cross section view of still another tile of a semiconductor device, according to some embodiments.

FIG. 6 depicts an X-Y plane view of yet another semiconductor device, according to some embodiments.

FIG. 7 depicts a cross sectional view of yet another semiconductor device, according to some embodiments.

FIGS. 8, 9, 10, and 11 illustrate cross-sectional views of an example semiconductor device during various fabrication stages in accordance with some embodiments.

FIG. 12 is a flow diagram of a method for the fabrication of a semiconductor device, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, semiconductor devices are fabricated by a combination of front end of line (“FEOL”) processes, which manufacture semiconductor (e.g., silicon) dies, and back end of line (“BEOL”) processes, which package one or more of these dies into a semiconductor device that can interface with other devices. For example, the package may combine a plurality of semiconductor dies and can be configured to be attached to a printed circuit board or other interconnected substrate, which may, in turn, allow the plurality of semiconductor dies of the semiconductor device to interface with additional semiconductor devices or other devices, power sources, communication channels, etc.

Physical demands for device miniaturization, increasing connectedness, and power efficiency are driving increases to semiconductor device density. Some of this increase in density can be attributed to improvements in the FEOL processes, including die miniaturization. Modern packaging technologies (e.g., package on package (PoP), Fan-Out packaging (FO), etc.) are also driving miniaturization, intercommunication, power savings and other improvements. The one or more dies of these modern packages may be interconnected or connected to package inputs and/or outputs (I/O) by bond wires, through-silicon vias (TSVs), metallization layers/vias coupled to the silicon dies, etc. While such connections use sophisticated techniques, further improvements are needed to advance the state of the art.

Semiconductor devices can include a plurality of semiconductor dies. Various semiconductor dies can be bonded together to form a heterogeneous chip. For example, dies can be bonded front to back or back to back such that an active surface of each die can receive one or more signals from an adjoining, bonded die, or by a through silicon via (TSV) of the die or of an adjoining, bonded die. Semiconductor bridges can be formed between various semiconductor dies or chips to pass signals such as power delivery network signals (PDN), clocks, address, data signals, etc. Some semiconductor devices can include one or more non-adjoining chips or dies with an in interconnection therebetween such that the interconnection circuit can include multiple semiconductor bridges. Such interconnection circuits can result in latency, signal integrity issues, or an IR drop which is greater than a target value. A redistribution structure including a plurality of interconnect structures can be formed over the chips. For example, the redistribution structure can connect any number of adjacent or nonadjacent chips and can include connections having a distance less than a Manhattan distance between two chips.

Semiconductor devices can include a plurality of semiconductor dies. Semiconductor dies, as used herein, refers to as a portion of a semiconductor wafer having disposed thereupon one or more active circuits such as transistor logic, analog devices such as RF or filtering elements, diodes, etc. A plurality of interconnections between the active surface can be made with one or more layers such as metallization layers. The one or more layers can connect the circuits of the active surface of the semiconductor device with additional elements of the semiconductor device. The die in combination with the one or more metallization layers can be termed as a semiconductor chip. A plurality of semiconductor chips can be combined to form a larger chip. For example, chips can be combined to form memory stacks, heterogeneous chips (comprising one or more die types), or other chips. Die types can include a process node of a die or a function of a die (e.g., PDN, processing, graphics, volatile memory, non-volatile memory, etc.).

One or more chips can form a tile. For example, a plurality of semiconductor chips can be joined (e.g., bonded). For example, the chips can be stacked (e.g., at least partially overlap in a z-direction) and vertically bonded by the connection of TSV or other die to die connections. The connections can include a conductive element such as copper or aluminum. In some embodiments, an intermediate material (such as a solder bump) can be disposed between the interconnected dies. The presence of a solder bump can aid the self-alignment of the die connections. For example, the solder bump may allow slightly offset connectors to maintain a connection (e.g., a mechanical, electrical, or thermal connection). In some embodiments, no intermediate material may be present for at least some junctions. For example, the dies can be connected by copper to copper connections (which may be suitable for increased connection density, relative to at least some bump technologies). The connection can be die to die or can include one or more metallization layers. For example, the TSV can terminate on one or more metallization layers connected to the semiconductor die.

Adjacent tiles can include interconnections via a semiconductor bridge (e.g., a silicon bridge). Silicon bridges can include one or more conductive elements. For example, the semiconductor bridges can include metallization layers disposed along a semiconductor surface. The metallization layers can form lateral connection between the various chips. The semiconductor bridges may be of a higher density than other package connections. Some connections can extend through a plurality of semiconductor bridges (e.g., bridges between or within tiles). Each connection through a semiconductor bridge can include the distance of the bridge as well as one or more via structures connecting to the bridge, and any additional routing length. Some connections through a semiconductor bridge (e.g., a plurality of semiconductor bridges) can be associated with a latency, IR drop, or another signal integrity concern.

A redistribution structure can be formed over one or more tiles. The redistribution structure can include one or more interconnect structures. For example, the interconnect structures can include via structures and tracks to interconnect the semiconductor device. The interconnect structures can connect adjacent and non-adjacent tiles. For example, interconnect structures can extend along a diagonal lateral direction (e.g., along the X and Y directions). A Manhattan distance can be defined by the distance between two points based on one or more X-direction or Y-direction paths of travel. For example, the Manhattan distance of a point 1 unit in the X direction and 1 unit in the Y direction from another point is 2 (whereas the true distance is about 1.41). The interconnect structures of the redistribution structures can connect points at distances less than the Manhattan distance (e.g., with diagonal rails, relative to the X and Y coordinates, such as offset less than 90 degrees therefrom).

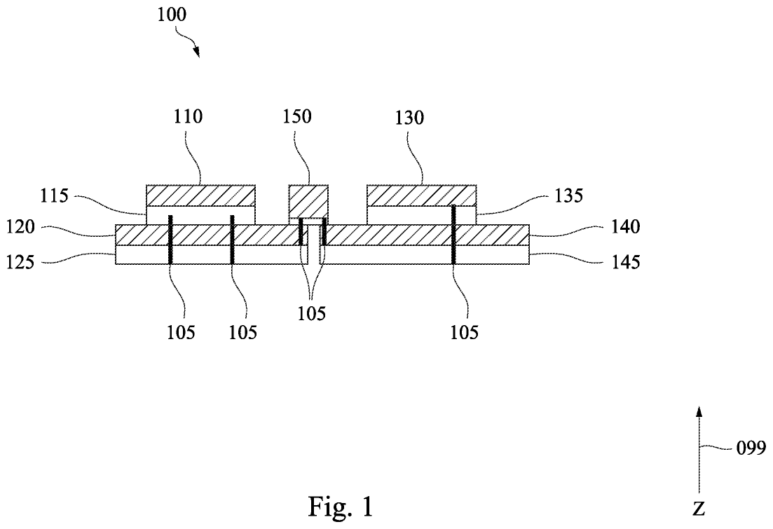

FIG. 1 depicts a tile 100 of a semiconductor device, in accordance with some embodiments. The tile 100 is depicted having an “upward” direction aligned with the Z-direction of an axis 099 of the semiconductor device. The “upward” direction can also be referred to as a thickness of the semiconductor device. For example, the semiconductor device can be configured to interface with a circuit board assembly or another substrate in a “downward” direction and can be connected thereto (e.g., mechanically thermally, or electrically). The connections can include various signals including PDN signals.

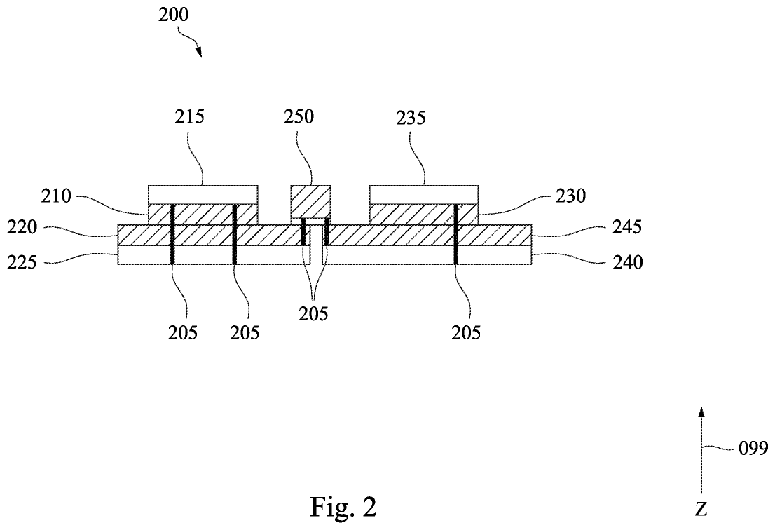

A first upper die 110 is bonded to a first lower die 120. For example, the bond can be with one or more TSV 105 or other connectors. The bond can be referred to as a front-to-back connection. The “front” of the first upper die 110 (i.e., the active surface which is connected to the one or more first upper metallization layers 115), is connected to the “back” of the first lower die 120. Some dies can be bonded in other configurations. For example, a front to front configuration, or the back to back configuration depicted in FIG. 2. The bond can be or include conductive interconnections. For example, the bond can be formed by connecting a conductive element of the upper die to a conductive element of the lower die (e.g., without an intermediate solder bump), which is referred to herein as hybrid bonding and can be achieved by a hybrid bonding technique. For example, the respective elements can be copper or aluminum and the bonding can be referred to as hybrid copper bonding or hybrid aluminum bonding.

The conductive elements can be or include TSV 105. For example, upper and lower dies or die assemblies can be connected by hybrid bonding through a plurality of TSV 105. The first lower die metallization structure 125 can be configured to interface with the TSV 105, and additional layers of the semiconductor device. For example, the first lower die metallization structure 125 can interface with one or more package layers including C2 bumps, C4 Bumps, via structures, integrated passive devices (IPD), interposers, under-bump metallurgy, or other intermediate connections. For example, the semiconductor device can include terminals configured to receive signals such as power, ground, and data. The various signals can pass through the semiconductor device terminals, through one or more intermediate connections, to one or more TSVs 105, which can traverse the first lower die 120, and connect to the first upper die 110 (e.g., through the first upper metallization layers 115). The TSV can also pass signals between the circuits of the first upper die 110 and the first lower die 120 such as local address busses. For example, the first upper die 110 can be a memory device (e.g., one or more layers of a high bandwidth memory (HBM)) and the TSVs can connect the memory to the first lower die 120, which can be an additional memory device, or a processing device to access the memory device.

The first lower die 120 is connected to a first semiconductor bridge 150. The semiconductor bridge 150 can connect semiconductor dies within a tile 100, or between tiles 100. For example, one or more first semiconductor bridges 150 can bound one or more edges of one or more tiles 100 to interconnect various dies or die assemblies disposed within the one or more tiles 100. In some embodiments, a semiconductor die of the semiconductor bridge can lack circuits on an active surface, and may include one or more metallization layers to interconnect other semiconductor chips (e.g., the die may be a substrate for the metallization layers). For example, the first semiconductor bridge 150 can bond the first upper die 110 and first lower die 120 to a second upper die 130 and second lower die 140. The second upper die 130 and second lower die 140 can be bonded by the same or another connection (e.g., can be hybrid bonded). The second upper die 130 and second lower die 140 can be similar to the first upper die 110 and second lower die 120. The various dies can be a repeating pattern of circuit elements (e.g., memory, compute, graphics, artificial intelligence optimized cores, etc.) such that additional dies increase a performance or capacity of a device. The various dies can execute unique functions (e.g., heterogeneous functions) such that the additional dies increase functionality of the device. The various dies can interoperate by standard or non-standard connections (e.g., physical and logical) over the first semiconductor bridge 150.

FIG. 2 depicts another tile 200 of a semiconductor device, according to some embodiments. The tile 200 is depicted in a back to back configuration, wherein the active surfaces of the semiconductors dies are disposed in a direction away from each other. A first upper die 210 and a first lower die 220 are joined by a plurality of TSV 205, and are connected to a respective first upper metallization layer 215 and first lower metallization layer 225. The semiconductor device also includes a second lower die 245 connected to a second lower metallization layer 240, and a second upper die 230 connected to a second upper metallization layer 235. A semiconductor bridge 250 is connected to each of the first lower die 220 and the second lower die 240. The depicted metallization layers herein, and throughout this disclosure can include one or more sub-layers. For example, the metallization layers can comprise several (e.g., five, eight, or nine) sublayers which can be referred to as M0, M1, M2 . . . , and the like.

In some embodiments, additional semiconductor dies can be bonded (e.g., hybrid bonded) to the tile. For example, the tile can contain a stack of 3 or 4 semiconductor dies, wherein the stacks are fully or partially overlapping according to a projection of the dies between the layers of the semiconductor device according to a Z-axis 099 of the semiconductor device. The heights of the semiconductor dies can be similar or dissimilar. For example, each die can include a plurality of TSV 205 which are aligned between the various dies and can define or affect the z-height (e.g., thickness) of a semiconductor die. For example, one or more semiconductor dies (e.g., a top or bottom die) may not include TSV 205 disposed therein, and may of greater thickness (e.g., the dies with TSV 205 can be thinned to reveal the TSV 205). The thickness of the semiconductor bridge can be based on a stack-up height of the various components of the semiconductor device. For example, the semiconductor bridge can be selected or planarized to match an upper dimension with at least one upper dimension of another element of the semiconductor device.

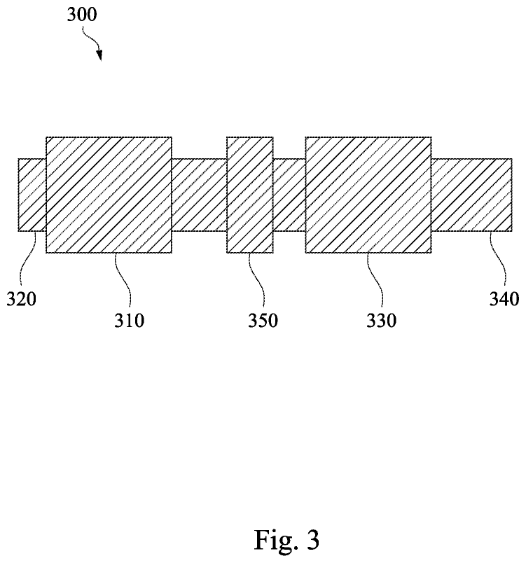

FIG. 3 depicts an X-Y plane view of a semiconductor device 300, according to some embodiments. The semiconductor device 300 can contain similar elements as the first tile 100 or the second tile 200. A first die 310 can be connected (e.g., by a hybrid bond) to a second die 320. A third die 330 can be connected to a fourth die 340 by a similar or different bond as the first die 310 and the second die 320. Each of the second dies 320 and fourth dies 340 are connected to a silicon bridge 350.

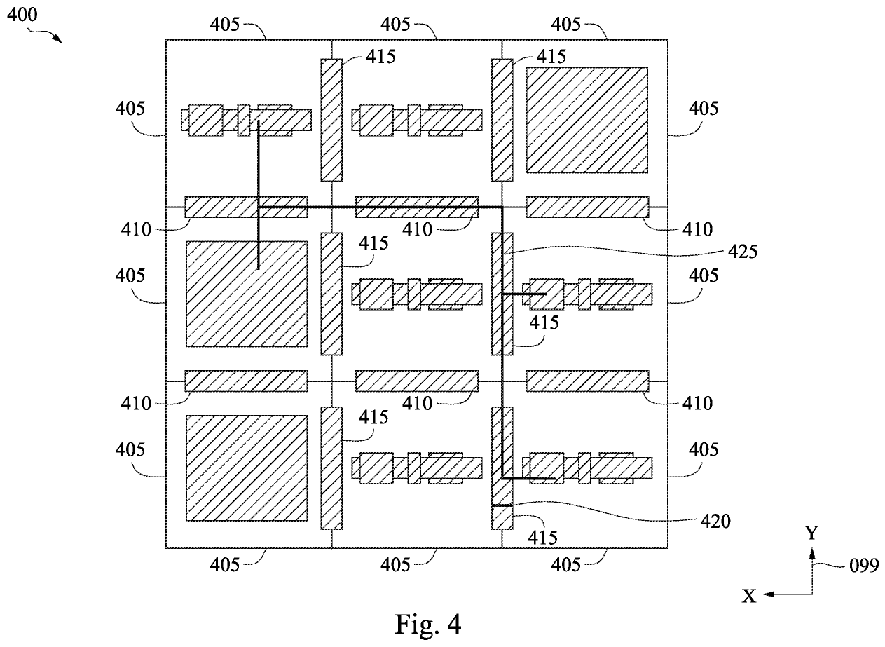

FIG. 4 depicts an X-Y plane view of another semiconductor device 400, according to some embodiments. The depicted semiconductor device includes nine tiles 405. Some semiconductor devices may include additional or fewer tiles, or differing tiles. For example, tiles can be of variable size, number, or function. Some tiles 405 can include scalable resources such as processors, memory, integrated voltage regulators, or communications interfaces. Disposed along the edges of the tiles, are a plurality of semiconductor bridges. Each tile 405 is generally aligned with an X-Y Axis 099. For example, the edges of each tile is generally aligned with the X direction of the axis 099 or the Y direction of the axis 099. Thus, the semiconductor bridges are also aligned with the X direction and Y direction, and can be subdivided into horizontal semiconductor bridges 410, disposed generally in an X direction, and vertical semiconductor bridges 415 disposed generally in a Y direction. The vertical and horizontal nomenclature is intended merely to describe the embodiment of FIG. 4, and is not intended to limit the position of a semiconductor device. Indeed, a semiconductor device can be positioned or mounted in any orientation or direction.

Interconnections between (or within) tiles 405 can be effected through the semiconductor bridges. The connections can join signals of adjacent tiles 405. For example, horizontal semiconductor bridges 410 can contain conductive elements joining vertically disposed adjacent tiles. Path 420 depicts one such connection. The connections can also include one or more lengthwise elements. For example, path 425 passes through a plurality of horizontal semiconductor bridges 410 and vertical semiconductor bridges 415 to connect adjacent and non-adjacent tiles. The connections can be routed through designated pathways of the semiconductor bridges, which may reduce a maximum semiconductor size relative to an interposer connection, and increase connection density relative to another package connection technology (e.g., an FR4 substrate).

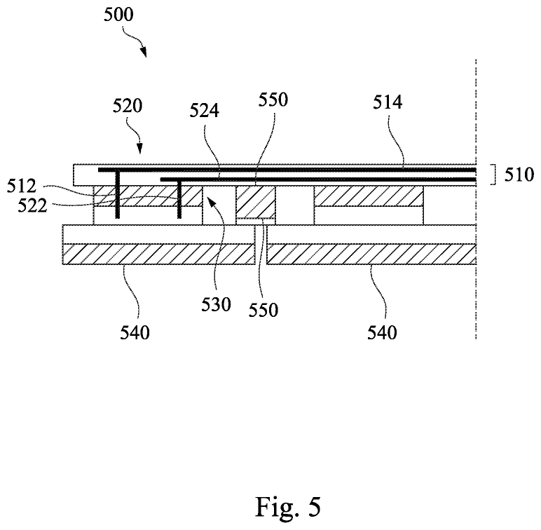

In some embodiments, the length of the connection nets can be a Manhattan distance, such that IR drop and latency can be higher than a desired level. Moreover, the dense connections of the semiconductor bridges can be of a fine pitch which can lead to further signal integrity signals of certain signals, such as global clocks and PDNs. For example, a network impedance of a connection can be other than a desired parameter. Referring now to FIG. 5, one or more tiles 500 of a semiconductor device can include a redistribution structure 510 disposed thereupon. The redistribution structure 510 can include one or more connection structures. For example, a redistribution structure can include a first connection structure 520, a second connection structure 530, and so on.

Still referring to FIG. 5, a cross section view of a semiconductor device, according to some embodiments, the connection structures can include one or more via structures 512, 522, and one or more lateral conductive structures 514, 424. For example, the one or more via structures 512, 522 can extend between the redistribution structure 510 and one or more chips 540 of the tile 500. For example, the tile 500 can include a plurality of hybrid bonded chips and interconnections through one or more semiconductor bridges 550. Some interconnections can be made through the redistribution structure 510. For example, low impedance or low-latency connections can be made in the redistribution structure 510. The redistribution structure 510 can also include various planes or shaped connectors. In some embodiments, the redistribution structure can contain one or more connections to an upper surface of a semiconductor device. For example, a PDN can include one or more passive components (e.g., bulk capacitance on an upper level of the semiconductor device) which can be connected to the semiconductor device via the redistribution structure 510.

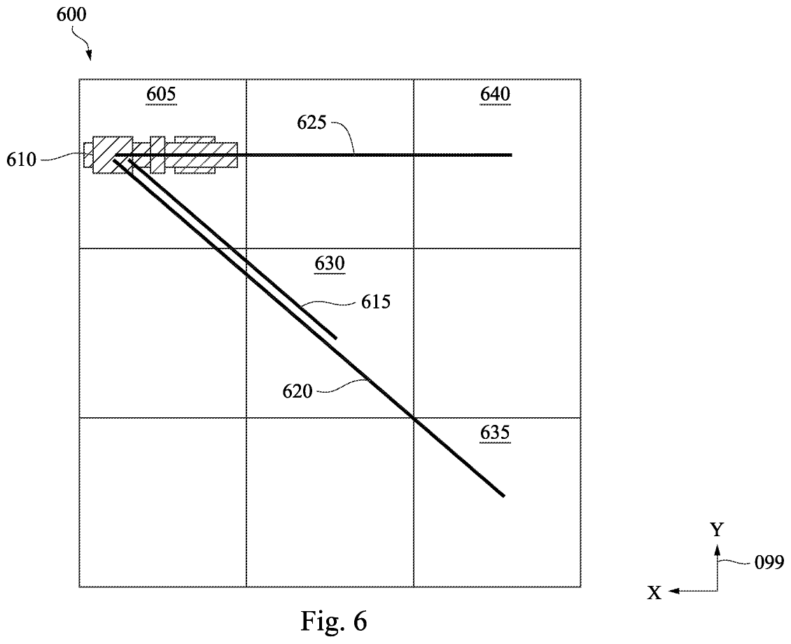

FIG. 6 depicts an X-Y plane view of yet another semiconductor device, according to some embodiments. A first tile 605 of a semiconductor device is populated by one or more semiconductor dies 610. The semiconductor dies are connected to a redistribution layer including a first interconnect structure 615, a second interconnect structure 620 and a third interconnect structure 625. Some embodiments can include additional or fewer interconnect structures. For example, some embodiments can include planes, buses, and other connections in the connection structure or the respective connection structures.

The first interconnect structure 615 connects to a second tile 630 of the semiconductor device, located diagonally adjacent to the first tile 605. The second interconnect structure 620 connects to a third tile 635 which is non-adjacent to the first tile, and located diagonally opposite the semiconductor device. The third interconnect structure 625 connects to a fourth tile 640 which is a nonadjacent tile located opposite the first tile 605 in the X direction. The redistribution structure can supplement or replace the one or more semiconductor bridges of the semiconductor device. For example, the redistribution structure can pass high current low latency signals, signals likely to result in interference in close proximity (e.g., as aggressor or victim transmission paths), and otherwise provide additional connectivity to the tiles of the semiconductor device. The various interconnect structures can include elements disposed at various angles, such as 90 degrees, more than 90 degrees, or less than 90 degrees.

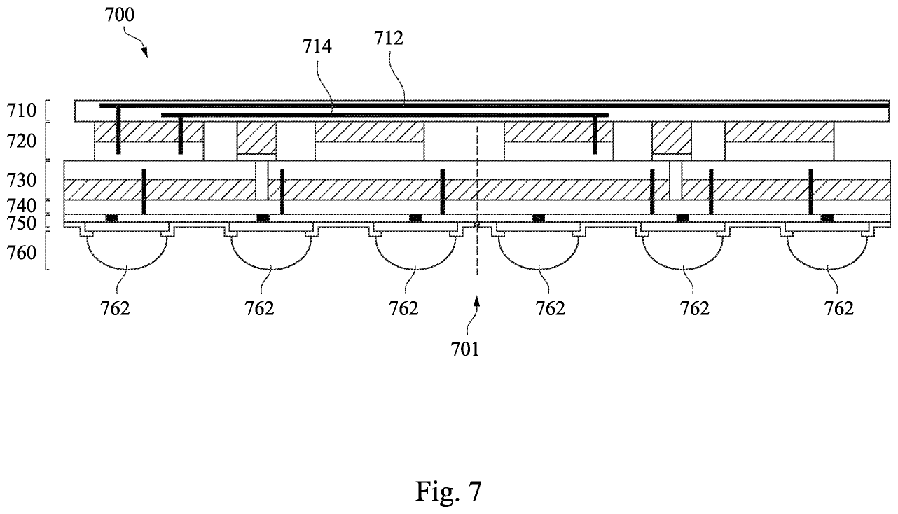

FIG. 7 depicts a cross sectional view of yet another semiconductor device 700, according to some embodiments. The semiconductor device 700 includes at least two non-adjacent tiles, as shown by a discontinuity line 701. Some embodiments of the semiconductor device 700 may contain adjacent tiles. A first layer 710 of the semiconductor device includes a redistribution structure to join the nonadjacent tiles. A first interconnect structure 712 is shown connected to one tile, and extending to an edge of the semiconductor device. The first interconnect structure 712 can connect to a tile which is not depicted, or the first interconnect structure 712 can be a ground plane which can increase a signal isolation of one or more additional signals, and improve connections (e.g., thermal, mechanical, or electrical). For example, if the surface of the first layer 710 is configured to interface to a heatsink, the first interconnect structure 712 can provide thermal coupling thereto. The second interconnect structure 712 connects the two depicted tiles. For example, the second interconnect structure 712 can pass a PDN or other signal between the two connections. The second interconnect structure 712 can be a multi-signal bus such as an address bus.

A second layer 720 of the semiconductor device 700 includes via structures connected to the first interconnect structure 712 and the second interconnect structure 714. The via structures can be TSV of one or more dies of the tiles. The second layer 720 of the semiconductor device 700 includes a semiconductor bridge, which may connect one or more signals within or between tiles of the semiconductor device. The third layer 730 of the semiconductor device 700 includes additional semiconductor dies, which are joined to the semiconductor dies of the second layer of the semiconductor device 700. For example, the layers can be joined by one or more interconnections formed without solder bumps along at least one junction. The additional semiconductor dies include TSV which connect the additional semiconductor dies to a fourth layer 740 of the semiconductor device. In some embodiments, the TSVs may extend through additional layers of the semiconductor device 700, such as the first layer 720 or the second layer 710. For example, the TSVs can pass through each semiconductor die and connect to still further semiconductor dies through the first layer 710 of the semiconductor device 700 (e.g., the redistribution structure).

The fourth layer 740 of the semiconductor device includes one or more interconnection layers. For example, one or more connections can be made between elements of the third layer 730 of the semiconductor device 700, and the fifth layer 750 of the semiconductor device. The fourth layer 740 can also connect elements of the third layer 730 of the semiconductor device 700 or the fifth layer 750 of the semiconductor device. The fifth layer 750 of the semiconductor device 700 can connect to one or more terminals 762 of the semiconductor device. For example, the fifth layer 750 of the semiconductor device 700 can include one or more conductive elements to join the terminals to additional levels of the semiconductor device 700.

A sixth layer 760 of the semiconductor device includes the terminals 762 of the semiconductor device 700, and can include intermediate connections such as UBM. The sixth layer can be configured to attach to an additional substrate. For example, the sixth layer 762 can connect to an interposer, or a printed circuit board assembly.

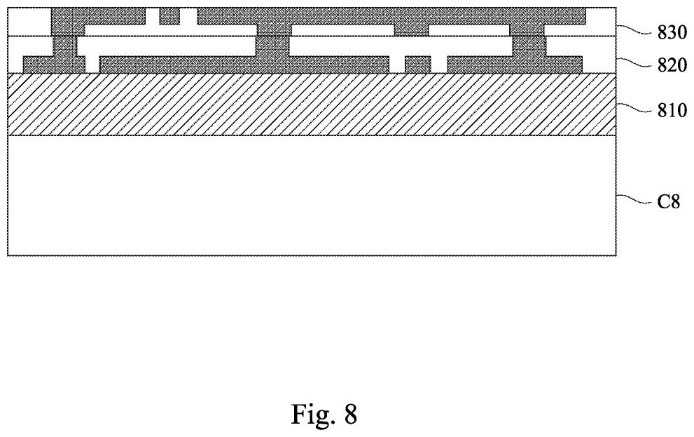

FIGS. 8 through 11 illustrate cross-sectional views of an example semiconductor device during various fabrication stages, in accordance with some embodiments. Referring to FIG. 8, a carrier substrate C8 is provided. The carrier substrate C8 may be glass, ceramic, a polymer based material, or a combination of materials. For example, a de-bonding layer such as a light-to-heat conversion release layer may be deposited over a Borosilicate glass body, which may, advantageously, enable the carrier substrate C8 to be removed from temporarily coupled layers while minimizing thermal expansion and contractions during subsequent processing steps. A first semiconductor die 810 is formed (e.g., placed or processed) over the carrier substrate C8. For example, the semiconductor die can be a wafer, or a cut portion thereof. The first semiconductor die 810 can have an active surface, having one or more circuits disposed thereupon. For example, the active surface can be formed along an the carrier substrate C8 or can be placed onto the substrate having an active surface. In some embodiments the substrate can be the silicon die. For example, a wafer can be included and thereafter removed (e.g., by grinding or another planarization process). In some embodiments, the wafer may be maintained in a completed semiconductor device at an original thickness.

The first semiconductor die 810 can include one or more TSV (not depicted). For example, the TSV can extend through a portion of the first semiconductor die 810, whereupon the first semiconductor die 810 can be reduced in dimension to allow the TSV to protrude through the Z-height of the semiconductor die. A first interconnection layer 820, is formed over the first semiconductor die 810, with a plurality of electrical pads to connecting to a plurality of electrical terminals along the active surface of the first semiconductor die 810, and connecting to various interconnect structures. The interconnect structures can comprise conductive material such as copper, nickel, titanium, a combination thereof, or the like. A second interconnection layer 830 is formed over the first interconnection layer. For example, the second interconnection layer can include one or more via structures and one or more lateral conductive elements to connect to the active surface of the semiconductor device. Some embodiments, can include additional or fewer layers. For example, each depicted layer can comprise a plurality of sublayers.

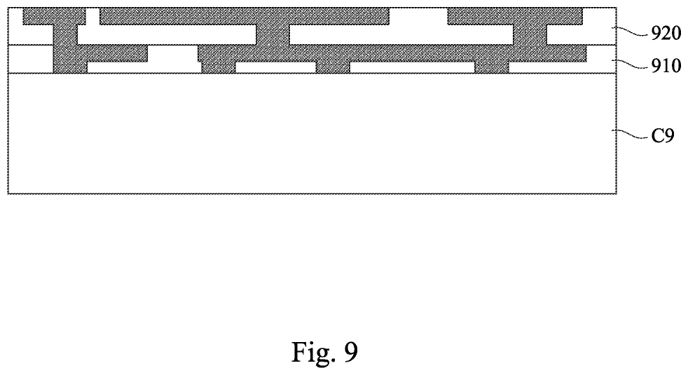

Referring now to FIG. 9, a redistribution structure is formed over another carrier substrate C9. The carrier substrate C9 can be similar or dissimilar to the carrier substrate C9 of FIG. 8. For example, the carrier substrate C9 can be configured for removal from the redistribution structure. The redistribution structure includes a first redistribution layer 910 formed over the carrier substrate C9 and a second redistribution layer 920 formed over the first redistribution layer 910. The redistribution layers can include connection structures formed from a plurality of vertical elements (e.g., via structures), and horizontal elements, which may be referred to herein as rails or tracks.

The connection structures can be configured to connect to a plurality of semiconductor dies. For example, the connection structures can include via structures (e.g., TSV, vias, TIV's) spaced at one or more pitch spacing. The via structures can be configured to connect to a plurality of tiles. For example, the via structures can be configured to connect to semiconductor dies of a variety of manufacturing processes, including semiconductor bridges. Some via structures can be configured to interface with additional packaging layers of the semiconductor device. For example, at least some signals can be configured to pass to the redistribution structure from another layer of the semiconductor device instead of or in addition to the TSV passing through the semiconductor dies.

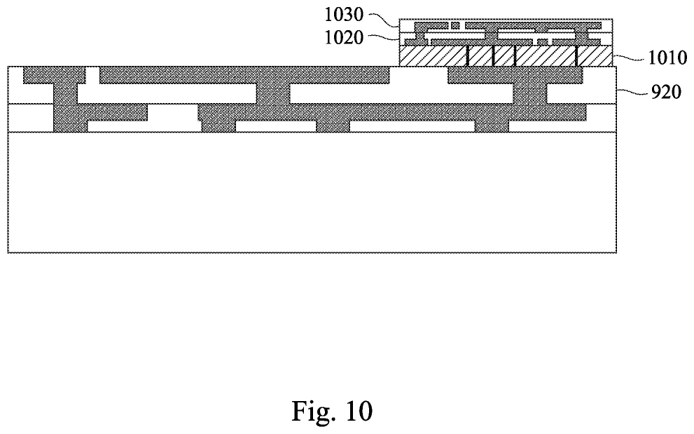

Referring now to FIG. 10, a second semiconductor die 1010, the first interconnection layer 1020, and the second interconnection layer 1030 are disposed over the assembly comprising the second redistribution layer 920. The second semiconductor die 1010 can be similar to the first semiconductor die 810. For example, the second semiconductor die 1010 can be of a similar function, size, or process as the first semiconductor die 810, or can be of different function, process or purpose. In some embodiments, the second semiconductor die 1010 can be a memory device which can be accessed by one or more processors of the first semiconductor die 810. Some embodiments can include additional layers (e.g., additional memory layers, or additional function layers such as artificial intelligence hardware, and other circuits). The second semiconductor die 1010 can be coupled to the second redistribution layer 920. For example, the second redistribution layer 920 can include one or more conductive elements to connect (e.g., electrically, mechanically or thermally) with the second semiconductor die 1010 (e.g., to TSV connected to the second semiconductor die 1010).

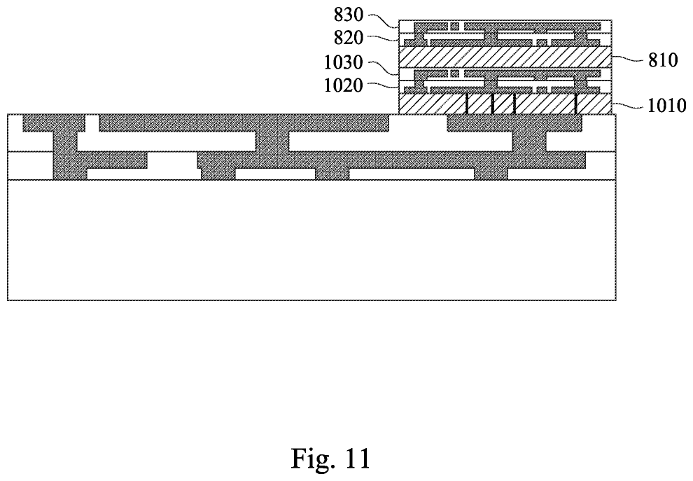

Referring now to FIG. 11, a first semiconductor die 810, a first interconnection layer 820, and a second interconnection layer 830 are formed over the assembly comprising the second semiconductor die 1110, the third interconnection layer 1120, and the fourth interconnection layer 1130. The semiconductor dies are bonded. For example, the semiconductor dies can be bonded directly or through one or more associated interconnection layers. For example, each semiconductor die can include a connector (e.g., a TSV or another via structure) configured to connect to a corresponding connector. For example, one or more of the connectors can include a solder bump, or a copper to copper connection based on a location and features (e.g., minimum alignment, and dishing of the connectors) of the corresponding connectors.

In some embodiments, additional layers can be formed over the depicted layers, or additional lateral dies can be added. For example, additional lateral dies can be connected by one or more semiconductor bridge, whereupon still further packaging layers can be formed, including one or more terminals of a semiconductor device. For example, the semiconductor device 700 of FIG. 7 can be formed.

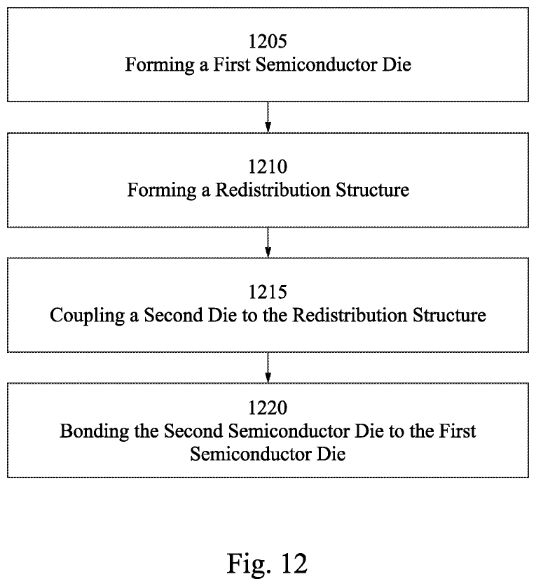

FIG. 12 is a flow diagram of a method 1200 for the fabrication of a semiconductor device, according to some embodiments. The method 1200 may be used to fabricate a semiconductor device having a plurality of semiconductor dies interconnected by one or more silicon bridges and one or more redistribution structures. For example, at least some of the operations described in the method 1200 may result in the semiconductor devices depicted in FIGS. 1-11. The disclosed method 1200 is disclosed as a non-limiting example, and additional operations may be provided before, during, and after the method 1200 of FIG. 12. Further, some operations may only be described briefly herein, however, one skilled in the art will understand that the disclosed operations may be performed in conjunction with other disclosed methods disclosed herein, or generally known in the art. For example, one skilled in the art will understand that additional layers, terminals, spacers, under-fills, and semiconductor bridges can be connected to the semiconductor device.

At operation 1205, a first semiconductor die is formed. The semiconductor die can be formed upon a substrate which can include another material, or the die can include the substrate. For example, a semiconductor die having a thickness to provide mechanical support of the active surface can be selected. In some embodiments, the semiconductor device can include a plurality of TSV. In some embodiments, forming the die can include the placement of TSV. For example, TSV can be formed through a first portion of the semiconductor device, and a second portion of the semiconductor device can be removed (e.g., by mechanical grinding, chemical-mechanical grinding, or another planarization process). One or more metallization layers can be formed upon the semiconductor die.

At operation 1210, a redistribution structure is formed. The redistribution structure can include one or more layers, and one or more interconnect structures can be formed within a layer or between the various layers. For example, redistribution structures can be configured to join one or more tiles of a semiconductor device, which may also include one or more semiconductor bridges (e.g., silicon bridges). The redistribution structure can include a first interconnect structure extending in a first direction (e.g., the X direction), a second interconnect structure extending in a second direction (e.g., the Y direction), and a third interconnect structure extending in a third direction (e.g., diagonally, in a lateral direction which is neither the X direction nor the Y direction). Interconnect structures can transit in the Z direction. For example, various via structures such as TSV connecting to the one or more semiconductor dies can connect to or be comprised in the interconnect structures.

At operation 1215, a second die is coupled to the redistribution structure. The second die can be connected to the first die at the time of coupling. For example, operation 1215 can be performed subsequent to operation 1220. The connected die can include one or more metallization layers. For example, the one or more metallization layers can be formed (e.g., grown, placed, etched, etc.) prior or subsequent to coupling. In some embodiments, the active surface of the second semiconductor die can face in a direction of the redistribution structure, and can couple to the redistribution structure via one or more metallization layers disposed therebetween. In some embodiments, an active surface of the semiconductor die can face away from the redistribution structure, and the semiconductor die can be otherwise attached thereto (e.g., mechanically by a die attach film, or by a plurality of TSV passing through the second semiconductor die).

At operation 1220, the second semiconductor die is bonded to the first semiconductor die. The second semiconductor die can be bonded to the first semiconductor die similarly to the connection of the second semiconductor die and the redistribution structure (e.g., through metallization layers, TIVs, or other connectors). For example, in some embodiments, the second semiconductor die can be bonded through an intermediate device such as a semiconductor bridge. In some embodiments, further semiconductor dies can be attached to the semiconductor device. For example, stacks of semiconductor dies having TSV to interface therebetween can be bonded to the redistribution structure and to each other.

In some embodiments, the first semiconductor die, the second semiconductor die, and the various connections therebetween can be formed at wafer scale. For example, a first wafer comprising a plurality of first semiconductor dies can be connected to a second wafer comprising a plurality of second semiconductor dies. The wafers can be connected by one or more interconnection layers. For example, the wafers can be connected by the interconnection layers depicted in FIG. 8, fewer interconnection layers, or additional interconnection layers. The assembly of the semiconductor dies can comprise an addition of one or more semiconductor dies. For example, an assembly of five, ten, or 15 dies can be formed. The dies can be assembled with additional elements, such as additional redistribution structures before or after being separated to form semiconductor devices. For example, the two wafers can be diced and the resulting die assemblies can be formed over the redistribution structure.

In one aspect of the present disclosure, a semiconductor device is disclosed. The semiconductor device includes a plurality of bottom semiconductor dies. The semiconductor device includes a plurality of top semiconductor dies. Each of the plurality of top semiconductor dies can be bonded to a corresponding one of the plurality of bottom semiconductor dies. The semiconductor device includes a redistribution structure disposed opposite the plurality of top semiconductor dies from the plurality of bottom semiconductor dies and comprising a plurality of interconnect structures. A first one of the plurality of top semiconductor dies is connected to a second one of the plurality of top semiconductor dies via a first subset of the plurality of interconnect structures.

In another aspect of the present disclosure, a semiconductor device is disclosed. The semiconductor device includes a plurality of bottom semiconductor dies and a plurality of top semiconductor dies. Each of the plurality of top semiconductor dies are bonded to a corresponding one of the plurality of bottom semiconductor dies. The semiconductor device includes a redistribution structure disposed opposite the plurality of top semiconductor dies from the plurality of bottom semiconductor dies including a plurality of interconnect structures. The plurality of interconnect structures include a first interconnect structure extending in first direction. The plurality of interconnect structures include a second interconnect structure extending in second direction The plurality of interconnect structures include a third interconnect structure extending in third direction, the first to third directions being different from one another.

In yet another aspect of the present disclosure, a method for fabricating semiconductor devices is disclosed. The method can include forming a first semiconductor die on a first substrate. The method can include forming a redistribution structure on a second substrate, the redistribution structure including a plurality of interconnect structures. The method can include coupling a second semiconductor die to the redistribution structure. The method can include bonding the second semiconductor die to the first semiconductor die. The plurality of interconnect structures can include a first interconnect structure extending in first direction, a second interconnect structure extending in second direction, and a third interconnect structure extending in third direction. The first to third directions can be different from one another.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a plurality of bottom semiconductor dies;
a plurality of top semiconductor dies, each of the plurality of top semiconductor dies bonded to a corresponding one of the plurality of bottom semiconductor dies; and
a redistribution structure disposed opposite the plurality of top semiconductor dies from the plurality of bottom semiconductor dies and comprising a plurality of interconnect structures;
wherein a first one of the plurality of top semiconductor dies is connected to a second one of the plurality of top semiconductor dies via a first subset of the plurality of interconnect structures.

2. The semiconductor package of claim 1, wherein the first subset of the interconnect structures each extend along a first direction tilted from a second direction along which a third one of the plurality of top semiconductor dies is arranged and from a third direction along which a fourth one of the plurality of top semiconductor dies is arranged.

3. The semiconductor package of claim 2, further comprising a plurality of semiconductor bridges, each of the plurality of semiconductor bridges interposed between neighboring ones of the plurality of top semiconductor dies.

4. The semiconductor package of claim 2, wherein the third top semiconductor die is disposed immediately next to the first top semiconductor die along the second direction, and the fourth top semiconductor die is disposed immediately next to the first top semiconductor die along the third direction.

5. The semiconductor package of claim 2, wherein the second top semiconductor die is disposed immediately next to the first top semiconductor die along the first direction.

6. The semiconductor package of claim 1, wherein the first top semiconductor die includes at least a first through via structure and the second top semiconductor die includes at least a second through via structure, and wherein the first through via structure and the second through via structure are electrically coupled to each other through the first subset of the interconnect structures.

7. The semiconductor package of claim 1, further comprising a plurality of connectors disposed opposite the plurality of bottom semiconductor dies from the plurality of top semiconductor dies.

8. The semiconductor package of claim 1, wherein the first top semiconductor die is connected to a fifth one of the plurality of top semiconductor dies via a second subset of the plurality of interconnect structures.

9. The semiconductor package of claim 8, wherein the first subset of the interconnect structures and the second subset of the interconnect structures extend in parallel with each other.

10. A semiconductor package, comprising:
a plurality of bottom semiconductor dies;
a plurality of top semiconductor dies, each of the plurality of top semiconductor dies bonded to a corresponding one of the plurality of bottom semiconductor dies; and
a redistribution structure disposed opposite the plurality of top semiconductor dies from the plurality of bottom semiconductor dies and comprising a plurality of interconnect structures;
wherein the plurality of interconnect structures at least include a first interconnect structure extending in first direction, a second interconnect structure extending in second direction, and a third interconnect structure extending in third direction, the first to third directions being different from one another.

11. The semiconductor package of claim 10, wherein a first one of the plurality of top semiconductor dies is connected to a second one of the plurality of top semiconductor dies via the first interconnect structure, and wherein the first top semiconductor die is disposed immediately next to the second top semiconductor die along the first direction.

12. The semiconductor package of claim 10, wherein a first one of the plurality of top semiconductor dies is connected to a third one of the plurality of top semiconductor dies via the second interconnect structure, and wherein the first top semiconductor die is disposed immediately next to the third top semiconductor die along the second direction.

13. The semiconductor package of claim 10, wherein a first one of the plurality of top semiconductor dies is connected to a fourth one of the plurality of top semiconductor dies via the third interconnect structure, and wherein the first top semiconductor die is disposed next to the fourth top semiconductor die along the third direction.

14. The semiconductor package of claim 10, wherein the third direction is tilted from any of the first direction or the second direction with an angle less than 90 degrees.

15. The semiconductor package of claim 10, further comprising a plurality of connectors disposed opposite the plurality of bottom semiconductor dies from the plurality of top semiconductor dies.

16. The semiconductor package of claim 10, wherein each of the plurality of top semiconductor dies includes at least one through via structure connecting to a corresponding one of the interconnect structures.

17. The semiconductor package of claim 10, wherein each of the top semiconductor dies is bonded to the corresponding bottom semiconductor die through a hybrid bonding technique.

18. A method for manufacturing semiconductor packages, comprising:
forming a first semiconductor die on a first substrate;
forming a redistribution structure on a second substrate, the redistribution structure including a plurality of interconnect structures;
coupling a second semiconductor die to the redistribution structure; and
bonding the second semiconductor die to the first semiconductor die;
wherein the plurality of interconnect structures include a first interconnect structure extending in first direction, a second interconnect structure extending in second direction, and a third interconnect structure extending in third direction, and wherein the first to third directions are different from one another.

19. The method of claim 18, concurrently with coupling the second semiconductor die to the redistribution structure, further comprising:
coupling a third semiconductor die to the redistribution structure, wherein the third semiconductor die is in electrical contact with the second semiconductor die via the first interconnect structure;
coupling a fourth semiconductor die to the redistribution structure, wherein the fourth semiconductor die is in electrical contact with the second semiconductor die via the second interconnect structure; and
coupling a fifth semiconductor die to the redistribution structure, wherein the fifth semiconductor die is in electrical contact with the second semiconductor die via the third interconnect structure.

20. The method of claim 18, further comprising forming a through via structure in the second semiconductor die, wherein the through via structure is in electrical contact with at least one of the first interconnect structure, the second interconnect structure, or the third interconnect structure.
